(19) United States
(12) Patent Application Publication
(10) Pub. No.: US 2024/0222406 A1
(43) Pub. Date: Jul. 4, 2024

(54) PIXEL UNIT, PHOTODETECTOR AND FABRICATION METHOD THEREOF

(71) Applicants: Semiconductor Manufacturing International (Beijing) Corporation, Beijing (CN); Semiconductor Manufacturing International (Shanghai) Corporation, Shanghai (CN)

(72) Inventors: Xing CHEN, Beijing (CN); Zhigao WANG, Beijing (CN)

(21) Appl. No.: 18/400,725

(22) Filed: Dec. 29, 2023

(30) Foreign Application Priority Data
Dec. 30, 2022 (CN) 202211732341.9

(51) Int. Cl. H01L 27/146

(52) U.S. Cl. CPC H01L 27/1463; H01L 27/14636; H01L 27/14643; H01L 27/14683

(57) ABSTRACT

Pixel units, photodetectors and fabrication methods of photodetectors are provided. The Pixel unit include a base substrate; a first deep trench isolation structure located in the base substrate and extending in a first direction; a second deep trench isolation structure located in the base substrate, electrically insulated from the first deep trench isolation structure and extending in a second direction intersecting the first direction, and a photosensitive element located in a portion of the base substrate surrounded by the first deep trench isolation structure and the second deep trench isolation structure and connected in series with the first deep trench isolation structure. The second deep trench isolation structure includes a first conductive layer, a second conductive layer and a dielectric layer between the first conductive layer and the second conductive layer.

### CROSS-REFERENCE TO RELATED APPLICATION

This application claims the priority of Chinese Patent Application No. 202211732341.9, filed on Dec. 30, 2022, the content of which is incorporated by reference in its entirety.

### TECHNICAL FIELD

The present disclosure generally relates to the field of photodetector technologies and, more particularly, relates to pixel units, photodetectors and fabrication methods.

### BACKGROUND

Due to the characteristics of its application scenarios, the core performance requirements of the automotive three-dimensional range imaging system include long detection distance, high environmental background brightness, and fast driving speed. Therefore, compared with the direct time of fly (DToF) system used by mobile terminals, optical sensors usually have performance requirements such as high gain, high sensitivity, and high temporal resolution.

A common form of photodetectors in a three-dimensional range imaging system is a silicon photomultiplier (SiPM). A silicon photomultiplier is composed of multiple single-photon avalanche diodes (SPAD) connected in parallel. Usually, each SPAD unit is independently connected in series with a quenching resistor. The cathodes and anodes of multiple SPAD units with quenching resistors are connected in parallel to form an array as a pixel to output a signal. Multiple arrays can achieve the three-dimensional imaging.

The high time-resolution requirement of the photodetector of the three-dimensional range imaging system requires that the entire system of photodetectors and readout circuits have lower parasitic resistance and parasitic capacitance to shorten the recovery time of SPAD as much as possible.

The high gain requirements of three-dimensional range imaging systems often require a higher overvoltage of SPAD to obtain higher photon detection efficiency, thus the operating voltage of SPAD is higher. This poses higher challenges to the device's performance, such as electrical isolation and direct current resistance (DCR) reduction.

However, SiPM formed by existing methods often has problems such as limited photosensitive area and high process cost, etc. The disclosed pixel units, photodetectors and methods for forming the photodetectors are directed to solve one or more problems set forth above and other problems in the art.

### SUMMARY

One aspect of the present disclosure provides a pixel unit. The pixel unit includes a base substrate; a first deep trench isolation structure located in the base substrate and extending in a first direction; and a second deep trench isolation structure located in the base substrate, electrically insulated from the first deep trench isolation structure and extending in a second direction intersecting the first direction. The second deep trench isolation structure includes a first conductive layer, a second conductive layer and a dielectric layer between the first conductive layer and the second conductive layer, and a stacking direction of the first conductive layer, the dielectric layer and the second conductive layer may be parallel to a surface of the base substrate and perpendicular to the second direction. The pixel unit also includes a photosensitive element located in a portion of the base substrate surrounded by the first deep trench isolation structure and the second deep trench isolation structure and connected in series with the first deep trench isolation structure.

Optionally, the pixel unit further includes an insulation member located in a portion of the base substrate at an intersection position between the first deep trench isolation structure and the second deep trench isolation structure.

Optionally, in a direction parallel to a surface of the base substrate and perpendicular to the first direction, a size of the insulation member is smaller than a size of the first deep trench isolation structure; and in a direction parallel to the surface of the base substrate and perpendicular to the second direction, a size of the insulation member is smaller than a size of the second deep trench isolation structure.

Optionally, the first deep trench isolation structure includes a third conductive layer and a linear layer located between the third conductive layer and the base substrate; and the second deep trench isolation structure further includes a linear layer located between the first conductive layer and the base substrate and between the second conductive layer and the base substrate, respectively.

Optionally, the liner layer and the insulation layer are an integrated structure.

Optionally, at least one of the first conductive layer, the second conductive layer and the third conductive layer is a doped polysilicon layer.

Optionally, in at least one of the first conductive layer, the second conductive layer and the third conductive layer, a doping concentration on one of its sides facing away from the base substrate is greater than a doping concentration on another side facing the base substrate.

Optionally, in the stacking direction parallel to the surface of the substrate and perpendicular to the second direction, a size of the dielectric layer ranges from approximately 50 nm to 300 nm.

Optionally, the pixel unit further includes an interconnection structure electrically connected to the photosensitive element, the first deep trench isolation structure, the first conductive layer and the second conductive layer, respectively.

Optionally, the interconnection structure includes a first plug electrically connected to the photosensitive element; a second plug electrically connected to the first deep trench isolation structure; a third plug electrically connected to the second conductive layer; a fourth plug electrically connected to the first conductive layer; a first interconnection layer electrically connected to the first plug, the second plug and the third plug; and a second interconnection layer electrically connected to the fourth plug.

Optionally, the pixel unit further includes a fifth plug electrically connected to the first deep trench isolation structure; and a third interconnection layer electrically connected to the fifth plug.

Optionally, in the first direction, the second plug and the fifth plug are respectively located at both ends of the first deep trench isolation structure; and in the second direction, the third plug and the fourth plug are respectively located at both ends of the second deep trench isolation structure.

Another aspect of the present disclosure provides a photodetector. The photodetector includes a pixel unit. The pixel unit includes a base substrate; a first deep trench isolation structure located in the base substrate and extending in a first direction; and a second deep trench isolation structure located in the base substrate, electrically insulated from the first deep trench isolation structure and extending in a second direction intersecting the first direction. The second deep trench isolation structure includes a first conductive layer, a second conductive layer and a dielectric layer between the first conductive layer and the second conductive layer, and a stacking direction of the first conductive layer, the dielectric layer and the second conductive layer may be parallel to a surface of the base substrate and perpendicular to the second direction. The pixel unit also includes a photosensitive element located in a portion of the base substrate surrounded by the first deep trench isolation structure and the second deep trench isolation structure and connected in series with the first deep trench isolation structure.

Optionally, the photodetector includes a silicon photomultiplier tube; the photodetector includes multiple pixel units; and photosensitive elements of the multiple pixel units are connected in parallel.

Another aspect of the present disclosure provides a method for forming a photodetector. The method includes forming a base substrate; and forming a first deep trench isolation structure and a second deep trench isolation structure in the base substrate. The first deep trench isolation structure is electrically insulated from the second deep trench isolation structure, the first deep trench isolation structure extends in a first direction, the second deep trench isolation structure extends in a second direction, the first direction intersects the second direction, the second deep trench isolation structure includes a first conductive layer, a second conductive layer and a dielectric layer located between the first conductive layer and the second conductive layer, a stacking direction of the first conductive layer, the dielectric layer and the second conductive layer is parallel to a surface of the base substrate and perpendicular to the second direction. The method also includes forming a photosensitive element in a portion of the base substrate surrounded by the first deep trench isolation structure and the second deep trench isolation structure.

Optionally, the method further includes forming an insulation element in the base substrate at an intersection position between the first deep trench isolation structure and the second deep trench isolation structure.

Optionally forming the first deep trench isolation structure and the second deep trench isolation structure in the base substrate includes forming a trench network including a first trench extending in the first direction and a second trench extending in the second direction in the base substrate; forming an insulation element at an intersection position of the first trench and the second trench to block the first trench and the second trench; forming a third conductive layer in the first trench and a first conductive layer and a second conductive layer respectively on opposite sidewalls of the second trench; and forming a dielectric layer between the first conductive layer and the second conductive layer.

Optionally, the first trench includes a functional area and an isolation area, and in the first direction, the isolation area is located at both ends of the functional area; the second trench includes a functional area and an isolation area, and in the second direction, the isolation area is located at both ends of the functional area; and the insulation member is formed in the isolation area.

Optionally, a width of a trench in the isolation area is smaller than a width of a trench in the functional area; forming the insulation member to block the first trench and the second trench includes forming a linear layer covering a bottom and sidewalls of the first trench and a bottom and sidewalls second trench to fill an isolation area of the first trench and an isolation area of the second trench to form the insulation member; and the third conductive layer is formed on portions of the linear layer of the bottom and sidewalls of the first trench, and the first conductive layer and the second conductive layer are respectively formed on the bottom of the second trench and portions of the linear layer on the sidewalls of the second trench. Optionally, the first gate structure includes a first gate dielectric layer on the first polarization layer and a first gate electrode layer on the first gate dielectric layer.

Optionally, forming the first conductive layer, the second conductive layer and the third conductive layer includes forming a conductive material layer to fill the first trench and cover the sidewalls and the bottom of the second trench; removing a portion of the conductive material layer on the bottom of the second trench to expose the bottom of the second trench; and filling the second trench with an exposed bottom with the dielectric layer during forming the dielectric layer between the first conductive layer and the second conductive layer.

Thus, the technical solutions of the present disclosure may have the following advantages.

As disclosed, the second deep trench isolation structure electrically connected to the photosensitive element may include a first conductive layer, a second conductive layer and a dielectric layer; and the photosensitive element may be connected to the deep trench isolation structures in series. The first deep trench isolation structure may be suitable as a quench resistor for passive quenching, and the second deep trench isolation structure may be suitable as a capacitor structure for fast output. By utilizing the deep trench isolation structures and vertical space, the same-chip integration of resistors and capacitors may be achieved without occupying additional chip area. Thus, it may effectively break through the area limitation of the photosensitive area, effectively increase the fill factor of the effective occupied area of the photosensitive element and facilitate improving photon conversion efficiency.

In an optional solution of the present disclosure, the first conductive layer, the second conductive layer and the third conductive layer may be formed by a conductive material layer. Forming the first conductive layer, the second conductive layer and the third conductive layer through a one-step material deposition process may effectively simplify the process steps.

In an optional solution of the present disclosure, the first trench and the second trench may be formed by forming a trench network, and then the linear layer may be used to fill the isolation area of the first trench and the isolation area of the second trench to form the insulation element to block the first trench and the second trench to realize the segmentation of the first deep trench isolation structure and the second deep trench isolation. The shape of the trench network may define the distribution shape of the first deep trench isolation structure and the second deep trench isolation. There may be no need for a separate etching mask or a separate implant mask, which may effectively reduce the number of masks, conducive to process cost control and simplification of the process flow.

### BRIEF DESCRIPTION OF THE DRAWINGS

The following drawings are merely examples for illustrative purposes according to various disclosed embodiments and are not intended to limit the scope of the present disclosure.

FIG. 1 illustrates a pixel unit of a photodetector;

FIGS. 2-17 illustrate structures corresponding to certain stages during an exemplary fabrication process of a photodetector consistent with various disclosed embodiments of the present disclosure; and

FIG. 18 illustrates an exemplary fabrication process of a photodetector consistent with various disclosed embodiments of the present disclosure.

### DETAILED DESCRIPTION

Reference will now be made in detail to exemplary embodiments of the disclosure, which are illustrated in the accompanying drawings. Wherever possible, the same reference numbers will be used throughout the drawings to refer to the same or like parts.

Silicon photomultiplier (SiPM) often has limited photosensitive area and high process cost. To obtain higher overvoltage and lower recovery time, a commonly used readout circuit method in single-photon avalanche diodes (SPAD) arrays is composite quenching, including a quenching method combined with the gated active quenching realized by CMOS circuits and the passive quenching realized by large resistors in series. Such an approach often requires SPAD to be integrated with passive components such as resistors and capacitors on the same chip.

To achieve the same-chip integration of resistors, the quenching resistors in series between the SiPM and each SPAD are usually implemented in the form of polysilicon (Poly) resistors, that is, high resistance poly (HRP). To ensure that the high-voltage Poly and SPAD have the electrical isolation between source regions, high-potential Poly is usually set on the shallow trench isolation (STI) structure. At the same time, for the sake of optical isolation and electrical isolation, adjacent SPADs are set up with the deep trench isolation (DTI) structure.

FIG. 1 illustrates a cross-sectional view of a pixel unit of a photodetector. As shown in FIG. 1, setting up the shallow trench isolation structure 12 and the deep trench isolation structure 11 at the same time occupies a large substrate area, limits the increase in the area of the SPAD photosensitive area, and is not conducive to the improvement of photon detection efficiency.

Moreover, the deep trench isolation structure is usually made of polysilicon or silicon oxide (Oxide). Although it is the same polysilicon as the quench resistor, they are formed in different process steps and need to be deposited separately.

The steps of forming the quenching resistor include etching the polysilicon material layer to form a polysilicon layer; and implanting the polysilicon layer according to the resistance value requirements to form high-resistance polysilicon. The etching step and the implanting step require the use of different etching masks and implanting masks, and the use of multiple masks increases the process cost.

In addition, to realize the same-chip integration of capacitors, capacitors that achieve fast output usually use metal oxide metal (MOM) or metal insulator metal (MIM) structures formed by the back end of line (BEOL). Additional masks and process steps are required, and an additional substrate area is occupied.

The present disclosure provides a pixel unit, a photodetector and a method for forming a photodetector. The first deep trench isolation structure may be suitable as a quenching resistor for the passive quenching, and the second deep trench isolation structure may be suitable as a capacitor structure for the fast output. The utilization of the deep trench isolation structure and the vertical space may enable the integration of resistors and capacitors on the same chip without occupying additional chip area. It may effectively break through the area limit of the photosensitive area, effectively increase the fill factor of the effective occupied area of the photosensitive element and facilitate improving the photon conversion efficiency.

To make the above objectives, features and advantages of the present disclosure more obvious and understandable, specific embodiments of the present disclosure will be described in detail below with reference to the accompanying drawings.

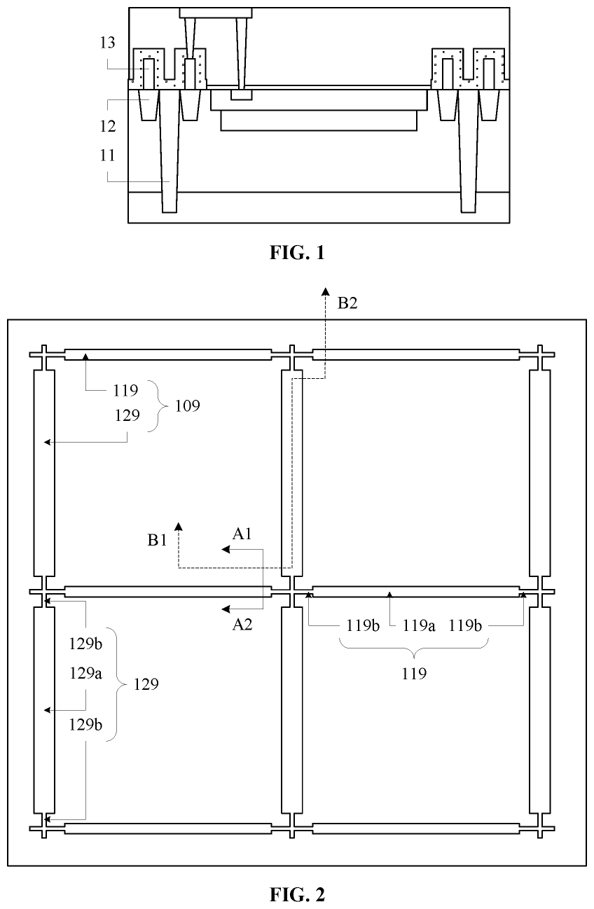

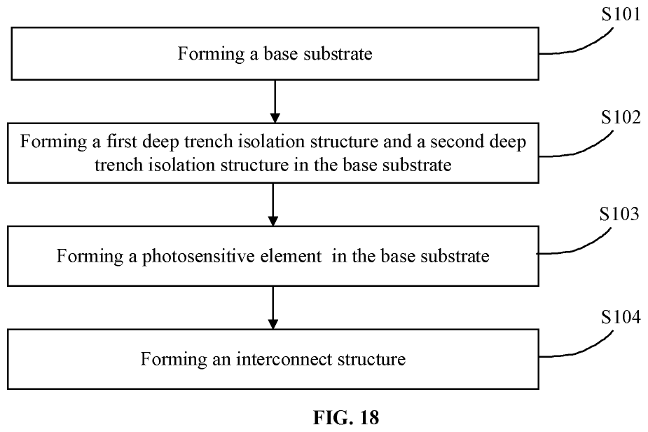

FIG. 18 illustrates an exemplary fabrication process of a photodetector consistent with various disclosed embodiments of the present disclosure. FIGS. 2-17 illustrate structures corresponding to certain stages during an exemplary fabrication process of a photodetector consistent with various disclosed embodiments of the present disclosure.

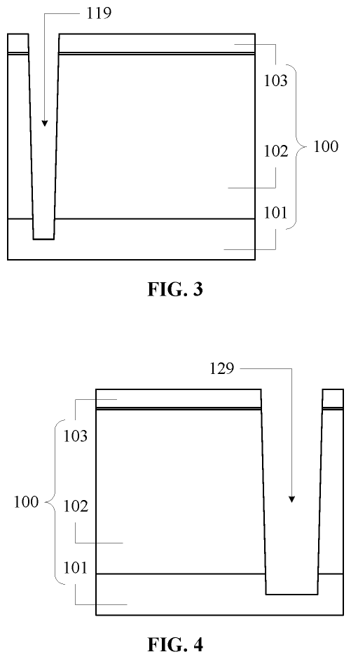

As shown in FIG. 22, at the beginning of the fabrication process, a base substrate with certain structures is provided (S101). FIGS. 2-4 illustrate a corresponding structure. FIG. 2 is a schematic top view of the intermediate structure of the method for forming a photodetector according to the present disclosure. FIG. 3 is a schematic A1A2-sectional view in FIG. 2. FIG. 4 is a schematic B1B2-sectional view in FIG. 2. As shown in FIGS. 2-4, a base substrate 100 is formed. The base substrate 100 may provide a process foundation and mechanical support for the subsequent processes.

As shown in FIGS. 3-4, the base substrate 100 may include a substrate 101 and an active layer 102. The active layer 102 may be formed on the substrate 101.

The substrate 101 may be a platform for the subsequent processes. The material of the substrate 101 may be selected from monocrystalline silicon, polycrystalline silicon or amorphous silicon, etc. The substrate 101 may also be selected from silicon, germanium, gallium arsenide compound, or silicon germanium compound, etc. The substrate 101 may also be selected from materials with an epitaxial layer or an epitaxial layer on silicon structure. The substrate 101 may also be made of other semiconductor materials, and the present disclosure does not impose any limitations on the material of the substrate 101.

In one embodiment, the substrate 101 is a silicon substrate. Referring to FIGS. 2-4, the substrate 101 may be a P-type doped silicon substrate.

The active layer 102 may include an active area for forming device structures. Referring to FIGS. 2-4, the active layer 102 may be an epitaxial layer. For example, the active layer 102 may be epitaxially grown on the substrate 101. In one embodiment, the active layer 102 may be an epitaxially grown P-type doped layer.

It should be noted that, in the embodiment shown in FIG. 3 and FIG. 4, the substrate 100 may also include an interface layer (not shown) on the active layer 102 and a protective layer (not shown) on the interface layer. The interface layer may be an oxide layer, and the protective layer may be a silicon nitride layer.

Returning to FIG. 18, after forming the base substrate, a first deep trench isolation structure and a second isolation structure may be formed in the base substrate (S102). FIGS. 5-12 illustrate corresponding structures.

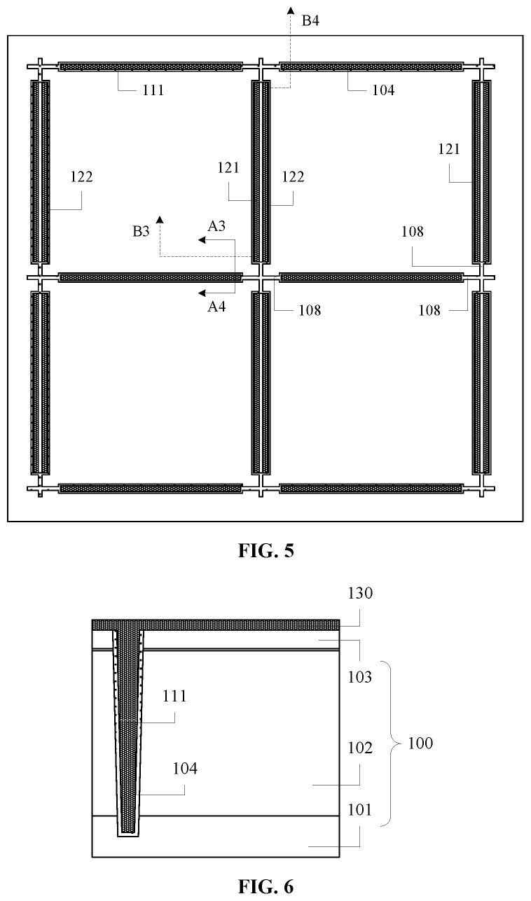

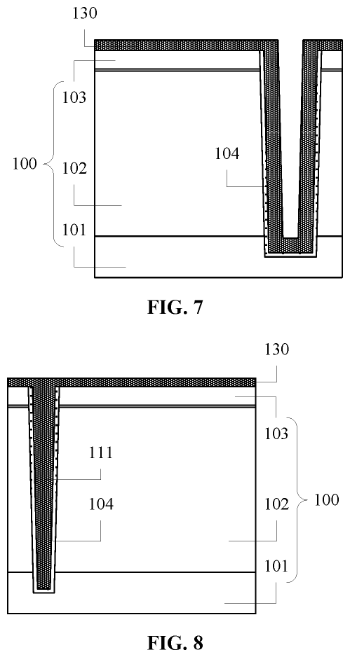

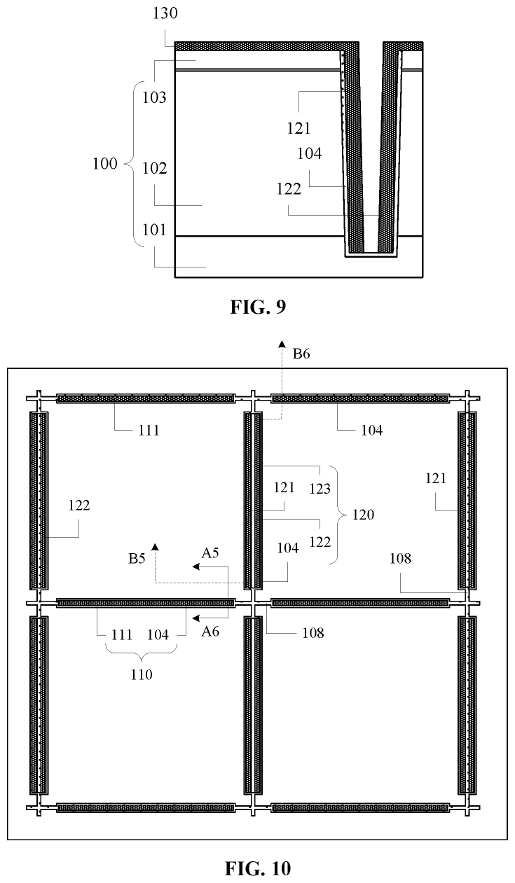

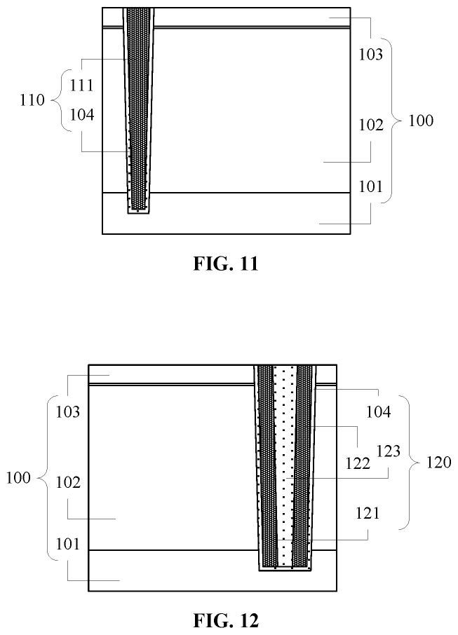

FIG. 5 and FIG. 10 are schematic top structural diagrams of the intermediate structures of the method for forming the photodetector shown in FIG. 2. FIG. 6 is a schematic A3A4-sectional view in the top view of the schematic diagram shown in FIG. 5. FIG. 7 is a B3B4-sectional view in the top view of the structural diagram shown in FIG. 5. FIG. 8 is a schematic cross-sectional structure diagram corresponding to the cross-sectional structural diagram shown in FIG. 6. FIG. 9 is the cross-sectional structural diagram corresponding to the cross-sectional structural diagram shown in FIG. 7. FIG. 11 is a schematic A5A6-sectional view in the top structural diagram shown in FIG. 10. FIG. 12 is a schematic 8586-sectional view in the top structural diagram shown in FIG. 10.

Referring to FIGS. 2-4, and as shown in FIGS. 5-12, a first deep trench isolation structure 110 and a second deep trench isolation structure 120 may be formed in the base substrate 100. The first deep trench isolation structure 110 and the second deep trench isolation structure 120 may be electrically insulated from each other. The first deep trench isolation structure 110 may extend in a first direction, the second deep trench isolation structure 120 may extend in a second direction, and the first direction may intersect the second direction.

The second deep trench isolation structure 120 may include a first conductive layer 121, a second conductive layer 122 and a dielectric layer 123 located between the first conductive layer 121 and the second conductive layer 122. The stacking direction of the first conductive layer 121, the dielectric layer 123 and the second conductive layer 122 may be parallel to the surface of the base substrate 100 and perpendicular to the second direction.

The first deep trench isolation structure 110 and the second deep trench isolation structure 120 may be located on the side of a photosensitive element to achieve an optical isolation. Further, the first deep trench isolation structure 110 may also be connected in series with the photosensitive element to be configured as a quench resistor for the passive quenching, and the second deep trench isolation structure 120 may be connected to the photosensitive element and may be configured as a capacitor structure for the fast output.

By utilizing the deep trench isolation structures and the vertical space, the resistors and capacitors may be integrated on a same chip without occupying additional chip area. Such a configuration may effectively break through the area limitation of the photosensitive area and effectively increase the fill factor of the effective occupied area of the photosensitive element. Correspondingly, it may be conducive to improving the photon conversion efficiency.

The photodetector may include a plurality of pixel units, and four pixel units of the plurality of pixel units are shown in FIGS. 2-12. As shown in FIG. 2, FIG. 5 and FIG. 10, the pixel unit may be square. Two mutually parallel first deep trench isolation structures 110 and two mutually parallel second deep trench isolation structures 120 may serve as the sides of the square to form the pixel unit. Two adjacent pixel units in the first direction may share a second deep trench isolation structure 120; and two adjacent pixel units in the second direction may share a first deep trench isolation structure 110.

In some embodiments of the present disclosure, the base substrate 100 may include a substrate 101 and an active area 102 stacked in sequence. The first deep trench isolation structure 110 and the second deep trench isolation structure 120 may pass through the active area 102. As shown in FIGS. 6-12, the first deep trench isolation structure 110 and the second deep trench isolation structure 120 may pass through the active region 102 and extend into a partial thickness of the substrate 101.

The steps of forming the electrically insulated first deep trench isolation structure 110 and the second deep trench isolation structure 120 in the base substrate 100 may include, as shown in FIGS. 2-4, forming a trench network 109 in the base substrate 100. The trench network 109 may include first trenches 119 extending in the first direction and second trenches 129 extending in the second direction. In one embodiment, the trench network 109 may be formed by an etching process using a mask.

As shown in FIG. 2, in the step of forming the first trenches 119 and the second trenches 129, the first trenches 119 may include a functional area 119a and an isolation area 119b. In the first direction, the isolation area 119b may be located at both ends of the functional area 119a. The second trenches 129 may include a functional area 129a and an isolation area 129b. In the second direction, the isolation area 129b may be located at both ends of the functional area 129a.

The functional area may be configured to form deep trench isolation structures. The isolation area may be configured to achieve electrical insulation between adjacent deep trench isolation structures.

In some embodiments, the first trench 119 and the second trench 129 may have a closing structure, for example the width of the trench in the isolation area may be smaller than the width of the trench in the functional area. For example, the width of the isolation area 119b of the first trench 119 may be smaller than the width of the functional area 119a of the first trench 119, and the width of the isolation area 129b of the second trench 129 may be smaller than the width of the functional area 129a of the second trench 129.

It should be noted that the width of the trench refers to the size of the trench in a direction parallel to the surface of the substrate 100 and perpendicular to the extension direction.

The first deep trench isolation structure 110 and the second deep trench isolation structure 120 may need to achieve an electrical insulation between adjacent pixel units.

Therefore, in the step of forming the trench network 109, the first trench 119 and the second trench 129 may be connected to each other. However, the first deep trench isolation structure 110 and the second deep trench isolation structure 120 may be insulated from each other. Thus, after forming the trench network 109, the method for forming the deep trench isolation structures may further include, as shown in FIGS. 5 to 7, blocking the first trench 119 and the second trench 129.

As shown in FIGS. 5-7, in the step of blocking the first trench 119 and the second trench 129, an insulation member 108 may be formed at the intersection position of the first trench 119 and the second trench 129 to block the first trench 119 and the second trench 129. The insulation member 108 may be configured to achieve an electrical insulation between the first deep trench isolation structure 110 and the second deep trench isolation structure 120.

As shown in FIGS. 2-7, the first trench 119 may include a functional area 119a and an isolation area 119b, and the second trench 129 may include a functional area 129a and an isolation area 129b. Accordingly, in the step of forming the insulation member 108 to block the first trench 119 and the second trench 129, the insulation member 108 may be formed in the isolation area.

As shown in FIGS. 5-7, the steps of forming the insulation member 108 to block the first trench 119 and the second trench 129 may include forming a linear layer 104 covering all the bottom and sidewalls of the first trench 119 and the bottom and sidewalls of the second trench 129. The linear layer 104 may fill the isolation area 119b of the first trench 119 and the isolation area 129b of the second trench 129 to form the insulation member 108. In one embodiment, the material of the linear layer 104 may be an oxide, which may be formed by a deposition method, such as chemical vapor deposition, physical vapor deposition, or an atomic layer deposition, etc.

Because the first trench 119 and the second trench 129 may have the closing structures, the size of the insulation member 108 may be smaller than the size of the first deep trench isolation structure 110 in the direction parallel to the surface of the substrate 100 and perpendicular to the first direction, and in a direction parallel to the surface of the substrate 100 and perpendicular to the second direction, the size of the insulation member 108 may be smaller than the size of the second deep trench isolation structure 120.

A deep trench isolation structure is formed with a trench with a closing structure, and an insulation structure is formed by a linear layer filling the trench in the isolation area. Accordingly, while achieving the electrical insulation between different deep trench isolation structures, the endpoints of the deep trench isolation structure may be defined. Accordingly, the number of patterning steps and the number of masks used may be effectively reduced.

Further, referring to FIGS. 5-9, the steps of forming the electrically insulated first deep trench isolation structure 110 and the second deep trench isolation structure 120 in the base substrate 100 may further include forming a third conductive layer 111 in the first trench 119, and a first conductive layer 121 and a second conductive layer 122 respectively on the opposite side walls of the second trench 129.

In some embodiments, as shown in FIGS. 5-7, the linear layer 104 may be formed on the bottom and sidewalls of the first trench 119 and the bottom and sidewalls of the second trench 129. Thus, in the step of forming the first conductive layer 121, the second conductive layer 122 and the third conductive layer 111, the third conductive layer 111 may be formed on the linear layer 104 on the bottom and sidewalls of the first trench 119 and the first conductive layer 121 and the second conductive layer 122 may be respectively formed on the linear layer 104 at the bottom and sidewalls of the second trench 129.

It should be noted that, in the embodiment shown in FIGS. 1-7, the insulation member 108 may be formed by filling the isolation area of the trench with the linear layer 104, thus the linear layer 104 and the insulation member 108 may be an integrated structure. For example, the linear layer 104 between the first conductive layer 121 and the base substrate 100 and between the second conductive layer 122 and the base substrate 100, the linear layer 104 between the third conductive layer 111 and the substrate 100, and the plurality of insulation members 108 may be of an integrated structure.

In one embodiment, the steps of forming the first conductive layer 121, the second conductive layer 122 and the third conductive layer 111 may include, as shown in FIGS. 5-7, forming a conductive material layer 125. The conductive material layer 125 may fill the first trench 119 and cover the sidewalls and bottom of the second trench 129. Then, as shown in FIGS. 8-9, a portion of the conductive material layer 125 on the bottom of the second trench 129 may be removed to expose the bottom of the second trench 129,

The portion of the conductive material layer 125 filling the first trench 119 may form the third conductive layer 111 to form the first deep trench isolation structure 110. The portion of the conductive material layer 125 on the sidewalls of the second trench 129 may form the first conductive layer 121 and the second conductive layer 122 respectively to form the second deep trench isolation structure 120.

In one embodiment, in the step of forming the conductive material layer 125, the conductive material layer 125 may be a doped polysilicon layer, which may be formed by deposition methods, such as a chemical vapor deposition process, a physical vapor deposition process, or an atomic layer deposition process.

It should be noted that the first conductive layer 111 may be configured as a quench resistor. Therefore, the doping concentration of the conductive material layer 125 may be set based on the design requirements of the resistance of the quench resistor and combined with the size of the first conductive layer 111.

Then, a portion of the conductive material layer 125 on the bottom of the second trench 129 may be removed to disconnect the conductive material layer 125 on the opposite side walls of the second trench 129 to obtain the first conductive layer 121 and the second conductive layer 122 that are insulated from each other.

As shown in FIGS. 6-9, in the step of forming the conductive material layer 125, the conductive material layer 125 may also extend to the base substrate 100. Therefore, in the step of removing a portion of the conductive material layer 125 on the bottom of the second trench 129, the conductive material layer 125 on the bottom of the second trench 129 may be etched through maskless etching to expose the bottom of the second trench 129.

As shown in FIGS. 10-12, the step of forming the electrically insulated first deep trench isolation structure 110 and the second deep trench isolation structure 120 in the base substrate 100 may further include forming a dielectric layer 123 between first conductive layer 121 and the second conductive layer 122.

The dielectric layer 123 may be configurated to achieve the electrical insulation between the first conductive layer 121 and the second conductive layer 122 such that the first conductive layer 121, the dielectric layer 123 and the second conductive layer 122 may form a capacitive structure.

In one embodiment, in the step of forming the dielectric layer 123 between the first conductive layer 121 and the second conductive layer 122, the second trench 129 exposed at the bottom may be filled with the dielectric layer 123. The material of the dielectric layer 123 may be an oxide, and may be formed by a deposition method, such as a chemical vapor deposition process, a physical vapor deposition process, or an atomic layer deposition process, etc.

It should be noted that the capacitance value of the capacitive structure formed by the first conductive layer 121, the dielectric layer 123 and the second conductive layer 122 may be related to the size and material properties of the first conductive layer 121, the dielectric layer 123 and the second conductive layer 122. Therefore, according to the design requirements of the capacitance value of the capacitor structure for the fast output, in the step of filling the second trench 129 exposed at the bottom with the dielectric layer 123, in the direction parallel to the surface of the base substrate 100 and the stacking direction perpendicular to the second direction, the size of the dielectric layer 123 may be in the range of approximately 50 nm to 300 nm to ensure the voltage resistance of the capacitor structure.

It should be noted that in the step of forming the conductive material layer 125, the conductive material layer 125 may also extend to the base substrate 100. Therefore, before forming the dielectric layer 123 between the first conductive layer 121 and the second conductive layer 122, the conductive material layer 125 on the substrate 100 may be removed.

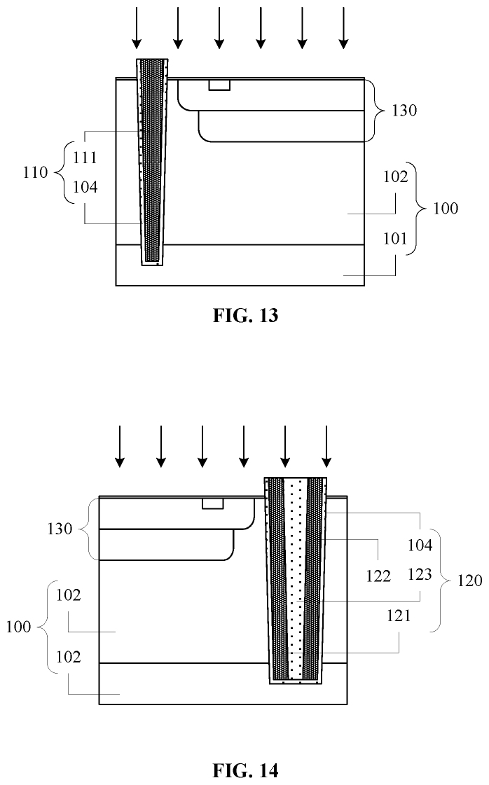

Returning to FIG. 18, after forming the first deep trench isolation structure and the second deep trench isolation structure, a photosensitive element may be formed in the base substrate (S103). FIGS. 13-14 illustrate a corresponding structure.

FIG. 13 is a schematic cross-sectional structural diagram corresponding to the schematic cross-sectional structural diagram shown in FIG. 11. FIG. 14 is a schematic cross-sectional structural diagram corresponding to the schematic cross-sectional structural diagram shown in FIG. 12.

As shown in FIGS. 13-14, after forming the first deep trench isolation structure 110 and the second deep trench isolation structure 120, a photosensitive element 130 may be formed in the base substrate 100 surrounded by the first deep trench isolation structure 110 and the second deep trench isolation structure 120.

In some embodiments, the photosensitive element 130 may be a single-photon avalanche diode. The photosensitive element 130 may be formed in the area surrounded by the first deep trench isolation structure 110 and the second deep trench isolation structure 120 by an ion implantation process. For example, the first deep trench isolation structure 110 and the second deep trench isolation structure 120 may surround the photosensitive element 130.

It should be noted that, as shown in FIGS. 11-12, the active layer 102 may also include an interface layer and a protective layer. Therefore, before forming the photosensitive element 130, the protective layer may be removed.

As shown in FIGS. 13-14, after forming the first deep trench isolation structure 110 and the second deep trench isolation structure 120, the method for forming the photodetector may further include performing an ion implantation process on the surfaces of the first conductive layer 121, the second conductive layer 122 and the third conductive layer 111 to increase the doping concentration to reduce the contact resistance. Therefore, the doping concentration on a side facing way the base substrate 100 of at least one of the first conductive layer 121, the second conductive layer 122 and the third conductive layer 111 100 may be greater than the side facing the base substrate 100.

The first conductive layer 121 and the second conductive layer 122 may be configured as two plates of a capacitor structure, the third conductive layer 111 may be configured as a quenching resistor. The higher doping concentration on the first conductive layer 121, the second conductive layer 122 and the third conductive layer 111 may effectively reduce the contact resistance of the first conductive layer 121, the second conductive layer 122 and the third conductive layer 111.

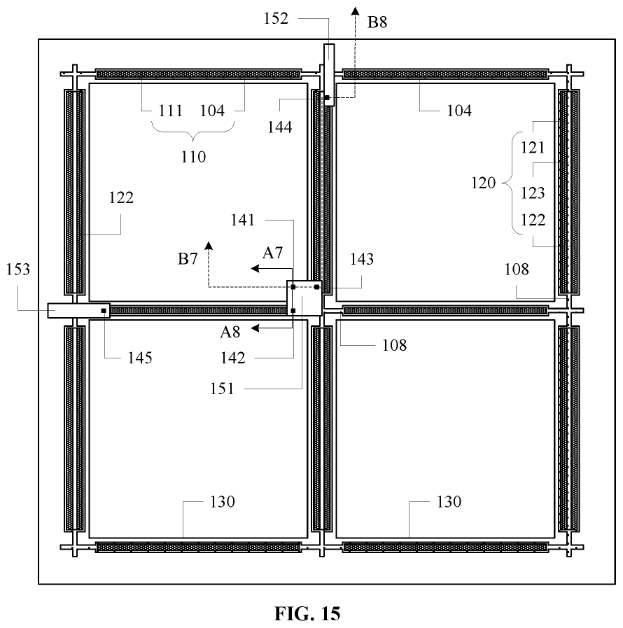

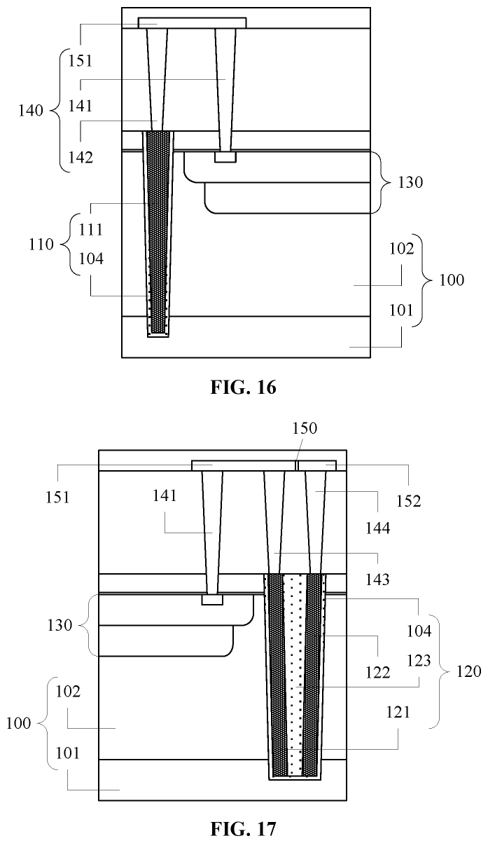

Returning to FIG. 18, after forming the photosensitive element, an interconnection structure may be formed (S104). FIGS. 15-17 illustrate a corresponding structure. FIG. 15 is a schematic top view of an intermediate structure of the method for forming a photodetector. FIG. 16 is a schematic A7A8-sectional structural view in FIG. 15. FIG. 17 is a schematic B7B8-sectional structural view in FIG. 15.

The first conductive layer 121 and the second conductive layer 122 may be configured as two plates of the capacitor structure, and the third conductive layer 111 may be configured as a quenching resistor. Therefore, as shown in FIGS. 15-17, the method for forming the photodetector may also include forming an interconnection structure 140. The interconnection structure 140 may be electrically connected to the photosensitive element 130, the first deep trench isolation structure 110, the first conductive layer 121 and the second conductive layer 122, respectively.

In one embodiment, the interconnection structure 140 may include a first plug 141 electrically connected to the photosensitive element 130, a second plug 142 electrically connected to the first deep trench isolation structure 110, a third plug 143 electrically connected to the first conductive layer 121, a fourth plug 144 electrically connected to the second conductive layer 122, a first interconnection layer 151 electrically connected to the first plug 141, the second plug 142 and the third plug 143, and a second interconnection layer 152 electrically connected to the fourth plug 144. The first interconnection layer 151 and the second interconnection layer 152 are electrically insulated from each other, e.g., by a structure 150. For example, the structure 150 may be an isolation structure, e.g., made of dielectric material(s), formed between the first interconnection layer 151 and the second interconnection layer 152 as shown in FIG. 17, to prevent electrical connection there-between. In another example, the structure 150 may be an air gap formed between the first interconnection layer 151 and the second interconnection layer 152.

In addition, the interconnection structure 140 may further include a fifth plug 145 electrically connected to the first deep trench isolation structure 110, and a third interconnection layer 153 electrically connected to the fifth plug 145.

As s shown in FIG. 15, in the first direction, the second plug 142 and the fifth plug 145 may be respectively located at both ends of the first deep trench isolation structure 110; and in the second direction, the third plug 143 and the fourth plug 144 may be respectively located at both ends of the second deep trench isolation structure 120.

As shown in FIGS. 16-17, the steps of forming the interconnection structure 140 may include, after forming the photosensitive element 130, forming a first interlayer dielectric layer (not labeled); forming a contact hole; filling the contact hole with a conductive material to form a plug; forming a second interlayer dielectric layer (not labeled) on the plug and the first interlayer dielectric layer; and forming an interconnection layer in the second dielectric layer.

The present disclosure also provides a pixel unit. FIGS. 15-17 illustrate an exemplary pixel unit consistent with various disclosed embodiments of the present disclosure.

As shown in FIGS. 15 to 17, the pixel unit may include a base substrate 100 and a first deep trench isolation structure 110. The first deep trench isolation structure 110 may be located in the base substrate 100, and extend in the first direction. The pixel unit may also include a second deep trench isolation structure 120 located in the substrate 100, and the second deep trench isolation structure 120 may be electrically insulated from the first deep trench isolation structure 110, and the second deep trench isolation structure 120 may extend in a second direction. The first direction may intersect the second direction. The second deep trench isolation structure 120 may include a first conductive layer 121, a second conductive layer 122 and a dielectric layer 123 located between the first conductive layer 121 and the second conductive layer 122. The stacking direction of the first conductive layer 121, the dielectric layer 123 and the second conductive layer 122 may be parallel to the surface of the substrate base 100 and perpendicular to the second direction. The pixel unit may also include a photosensitive element 130 located in the base substrate 100 surrounded by the first deep trench isolation structure 110 and the second deep trench isolation structure 120. The photosensitive element 130 may be connected in series with the first deep trench isolation structure 110.

The pixel unit may be formed by the forming method of the present disclosure. Therefore, the specific technical solution of the pixel unit may refer to the embodiments of the aforementioned forming method in the present disclosure and will not be repeated herein.

In addition, the present disclosure also provides a photodetector. The photodetector may include a pixel unit, and the pixel unit may be a pixel unit of the present disclosure.

The pixel unit may be formed by the formation method of the present disclosure. Therefore, the specific technical solution of the photodetector may be refer to the aforementioned embodiment of the pixel unit in the present disclosure and will not be repeated herein.

In some embodiments of the present disclosure, the photodetector may be formed by the forming method of the present disclosure. Therefore, the specific technical solution of the photodetector may also refer to the embodiments of the foregoing forming method in the present disclosure and will not be repeated herein.

Moreover, in some embodiments of the present disclosure, the photodetector may be a silicon photomultiplier tube, and the photodetector may include multiple pixel units, and the photosensitive elements 130 of the multiple pixel units may be connected in parallel.

To sum up, the second deep trench isolation structure electrically connected to the photosensitive element may include a first conductive layer, a second conductive layer and a dielectric layer; and the photosensitive element may be connected in series with the deep trench isolation structure. The first deep trench isolation structure may be suitable as a quench resistor for the passive quenching, and the second deep trench isolation structure may be suitable as a capacitor structure for the fast output. By utilizing the deep trench isolation structures and the vertical space, the resistors and capacitors may be integrated on the same chip without occupying additional chip area. Such a configuration may effectively break through the area limitation of the photosensitive area and effectively increase the fill factor of the effective occupied area of the photosensitive element, and may be conducive to improving photon conversion efficiency. Furthermore, the first conductive layer, the second conductive layer and the third conductive layer may be formed by a conductive material layer. Forming the first conductive layer, the second conductive layer and the third conductive layer through a one-step material deposition process may effectively simplify the process steps. In addition, by forming a trench network to form the first trench and the second trench, and then filling the isolation area of the first trench and the isolation area of the second trench with a linear layer to form the insulation structure, segmentation may be achieved to block the first trench and the second trench to form the first deep trench isolation structure and the second deep trench isolation structure. The shape of the trench network may define the distribution shape of the first deep trench isolation structure and the second deep trench isolation structure. There may be no need for a separate etching mask or a separate implant mask, which may effectively reduce the usage quantity of masks, and may be conducive to process cost control and simplification of process flow.

Although the present disclosure is disclosed as above, the present disclosure is not limited thereto. Any person skilled in the art can make various changes and modifications without departing from the spirit and scope of the present disclosure. Therefore, the protection scope of the present disclosure should be subject to the scope defined by the claims.

What is claimed is:

1. A pixel unit, comprising:
a base substrate;
a first deep trench isolation structure located in the base substrate and extending in a first direction;
a second deep trench isolation structure located in the base substrate, electrically insulated from the first deep trench isolation structure and extending in a second direction intersecting the first direction, wherein the second deep trench isolation structure includes a first conductive layer, a second conductive layer and a dielectric layer between the first conductive layer and the second conductive layer, and a stacking direction of the first conductive layer, the dielectric layer and the second conductive layer is parallel to a surface of the base substrate and perpendicular to the second direction; and
a photosensitive element located in a portion of the base substrate surrounded by the first deep trench isolation structure and the second deep trench isolation structure and connected in series with the first deep trench isolation structure.

2. The pixel unit according to claim 1, further comprising:
an insulation member located in a portion of the base substrate at an intersection position between the first deep trench isolation structure and the second deep trench isolation structure.

3. The pixel unit according to claim 2, wherein:
in a direction parallel to a surface of the base substrate and perpendicular to the first direction, a size of the insulation member is smaller than a size of the first deep trench isolation structure; and
in a direction parallel to the surface of the base substrate and perpendicular to the second direction, a size of the insulation member is smaller than a size of the second deep trench isolation structure.

4. The pixel unit according to claim 1, wherein:
the first deep trench isolation structure includes a third conductive layer and a linear layer located between the third conductive layer and the base substrate; and
the second deep trench isolation structure further includes a linear layer located between the first conductive layer and the base substrate and between the second conductive layer and the base substrate, respectively.

5. The pixel unit according to claim 4, wherein:
the liner layer and the insulation layer are an integrated structure.

6. The pixel unit according to claim 4, wherein:
at least one of the first conductive layer, the second conductive layer and the third conductive layer is a doped polysilicon layer.

7. The pixel unit according to claim 4, wherein:
in at least one of the first conductive layer, the second conductive layer and the third conductive layer, a doping concentration on one of its sides facing away from the base substrate is greater than a doping concentration on another side facing the base substrate.

8. The pixel unit according to claim 1, wherein:
in the stacking direction parallel to the surface of the substrate and perpendicular to the second direction, a size of the dielectric layer ranges from approximately 50 nm to 300 nm.

9. The pixel unit according to claim 1, further comprising:
an interconnection structure electrically connected to the photosensitive element, the first deep trench isolation structure, the first conductive layer and the second conductive layer, respectively.

10. The pixel unit according to claim 9, wherein the interconnection structure comprises:
a first plug electrically connected to the photosensitive element;
a second plug electrically connected to the first deep trench isolation structure;
a third plug electrically connected to the second conductive layer;
a fourth plug electrically connected to the first conductive layer;
a first interconnection layer electrically connected to the first plug, the second plug and the third plug; and
a second interconnection layer electrically connected to the fourth plug.

11. The pixel unit according to claim 10, wherein the interconnection structure further comprises:
a fifth plug electrically connected to the first deep trench isolation structure; and
a third interconnection layer electrically connected to the fifth plug.

12. The pixel unit according to claim 11, wherein:
in the first direction, the second plug and the fifth plug are respectively located at both ends of the first deep trench isolation structure; and
in the second direction, the third plug and the fourth plug are respectively located at both ends of the second deep trench isolation structure.

13. A photodetector, comprising:
a pixel unit, including:
a base substrate;
a first deep trench isolation structure located in the base substrate and extending in a first direction;
a second deep trench isolation structure located in the base substrate, electrically insulated from the first deep trench isolation structure and extending in a second direction intersecting the first direction, wherein the second deep trench isolation structure includes a first conductive layer, a second conductive layer and a dielectric layer between the first conductive layer and the second conductive layer, and a stacking direction of the first conductive layer, the dielectric layer and the second conductive layer is parallel to a surface of the base substrate and perpendicular to the second direction; and
a photosensitive element located in a portion of the base substrate surrounded by the first deep trench isolation structure and the second deep trench isolation structure and connected in series with the first deep trench isolation structure.

14. The photodetector according to claim 13, wherein:
the photodetector includes a silicon photomultiplier tube;
the photodetector includes multiple pixel units; and
photosensitive elements of the multiple pixel units are connected in parallel.

15. A method for forming a photodetector, comprising:
forming a base substrate;
forming a first deep trench isolation structure and a second deep trench isolation structure in the base substrate, wherein the first deep trench isolation structure is electrically insulated from the second deep trench isolation structure, the first deep trench isolation structure extends in a first direction, the second deep trench isolation structure extends in a second direction, the first direction intersects the second direction, the second deep trench isolation structure includes a first conductive layer, a second conductive layer and a dielectric layer located between the first conductive layer and the second conductive layer, a stacking direction of the first conductive layer, the dielectric layer and the second conductive layer is parallel to a surface of the base substrate and perpendicular to the second direction; and
forming a photosensitive element in a portion of the base substrate surrounded by the first deep trench isolation structure and the second deep trench isolation structure.

16. The method according to claim 15, further comprising:
forming an insulation element in the base substrate at an intersection position between the first deep trench isolation structure and the second deep trench isolation structure.

17. The method according to claim 15, wherein forming the first deep trench isolation structure and the second deep trench isolation structure in the base substrate comprises:
forming a trench network including a first trench extending in the first direction and a second trench extending in the second direction in the base substrate;
forming an insulation element at an intersection position of the first trench and the second trench to block the first trench and the second trench;
forming a third conductive layer in the first trench and a first conductive layer and a second conductive layer respectively on opposite sidewalls of the second trench; and
forming a dielectric layer between the first conductive layer and the second conductive layer.

18. The method according to claim 17, wherein:
the first trench includes a functional area and an isolation area, and in the first direction, the isolation area is located at both ends of the functional area;
the second trench includes a functional area and an isolation area, and in the second direction, the isolation area is located at both ends of the functional area; and
the insulation member is formed in the isolation area.

19. The method according to claim 18, wherein:
a width of a trench in the isolation area is smaller than a width of a trench in the functional area;
forming the insulation member to block the first trench and the second trench includes forming a linear layer covering a bottom and sidewalls of the first trench and a bottom and sidewalls second trench to fill an isolation area of the first trench and an isolation area of the second trench to form the insulation member; and
the third conductive layer is formed on portions of the linear layer of the bottom and sidewalls of the first trench, and the first conductive layer and the second conductive layer are respectively formed on the bottom of the second trench and portions of the linear layer on the sidewalls of the second trench.

20. The method according to claim 17, wherein forming the first conductive layer, the second conductive layer and the third conductive layer comprises:
forming a conductive material layer to fill the first trench and cover the sidewalls and the bottom of the second trench;
removing a portion of the conductive material layer on the bottom of the second trench to expose the bottom of the second trench; and
filling the second trench with an exposed bottom with the dielectric layer during forming the dielectric layer between the first conductive layer and the second conductive layer.
